(19) United States
(12) Patent Application Publication
(10) Pub. No.: US 2011/0067748 A1
(43) Pub. Date: Mar. 24, 2011

(54) SOLAR SYSTEM

(75) Inventor: Andre Pfeiffer, Leopoldshohe (DE)

(73) Assignee: Inventux Technologies AG, Berlin (DE)

(21) Appl. No.: 12/713,611

(22) Filed: Feb. 26, 2010

(30) Foreign Application Priority Data
Sep. 18, 2009 (DE) 10 2009 042 092.4

(51) Int. Cl. H01L 31/052; H01L 31/042

(52) U.S. Cl. 136/246; 136/244

(57) ABSTRACT

The present invention relates to a solar system comprising a plurality of solar modules, particularly photovoltaic modules, characterized in that the solar modules are arranged at least two different angles of inclination relative to a flat, particularly horizontal, base area, for instance a flat roof. According to a variant the present invention further relates to a solar system having a plurality of solar modules, wherein a reflecting element is arranged between two solar modules.

### CLAIM OF PRIORITY

The present patent application claims the priority benefit of the filing date of German Patent Application No. 10 2009 042 092.4, filed Sep. 18, 2009, the entire content of which is incorporated herein by reference in its entirety.

The present invention relates to a solar system comprising a plurality of solar modules, particularly photovoltaic modules, which are arranged on a flat, particularly horizontal, base area 39.

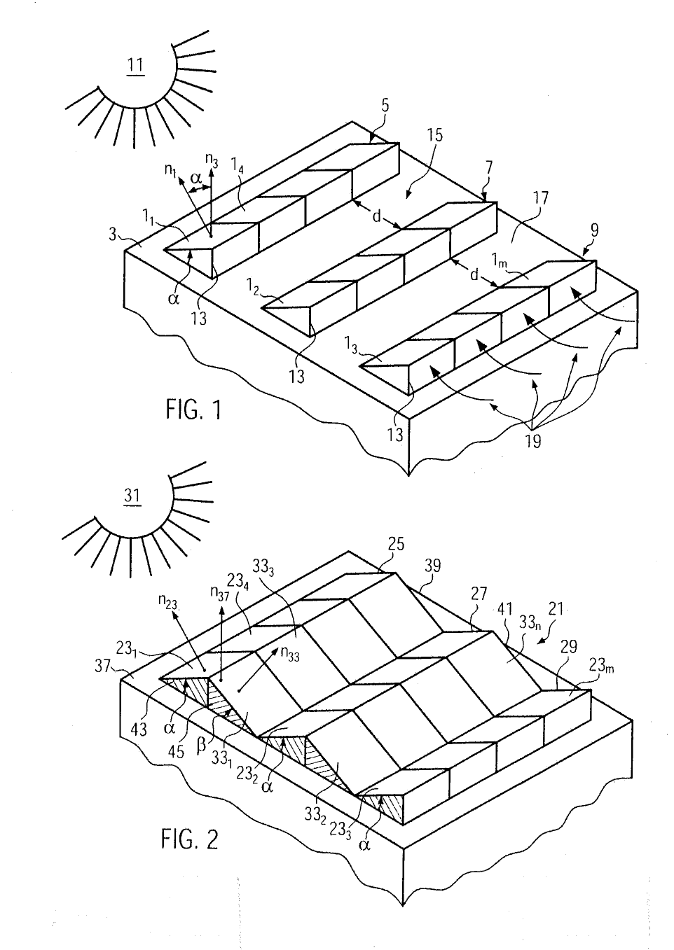

FIG. 1 shows such an arrangement of solar modules 1ᵢ with on a flat base area, for instance a flat roof 3 or an open field. The modules are for example photovoltaic modules for converting electro-magnetic radiation into electric current. The modules 1ᵢ are arranged on the roof 3 in a plurality of parallel rows 5, 7, 9 and oriented towards the sun 11 to optimize the generation of electric power. To this end the modules 1ᵢ, are oriented at an angle of inclination α. The angle α is here defined as the angle between the normal n₃ of the base area 3 as the first leg and the normal of the solar module n₁ as the second leg. Depending on the geographic position, said angle of inclination α is between 5° and 50° degrees. Less than 5° is disadvantageous because there will be no self-cleaning effect of the module any more. A corresponding support element 13 is used for an inclined positioning of the modules 1ᵢ.

To prevent shading of the modules of one row, here for example row 7 or 9, by the modules obliquely positioned in front thereof, here row 5 and 7, respectively, the rows are arranged at a distance d relative to one another. Due to the free spaces 15 and 17 created thereby between the module rows 5, 7, 9, the total area of the flat roof 3 is however only used in part for the generation of electric power.

Moreover, the inclined position of the modules 1ᵢ will create wind impact areas underneath the modules 1ᵢ if wind is blowing, as outlined by arrows 19, from the side opposite to the sun 11. To prevent a lifting of the modules 1ᵢ these modules are fixedly connected to the roof 3, or they are sufficiently loaded with sand bags, rocks, etc.

Starting from this, it is therefore the object of the present invention to provide a solar system with improved area exploitation and a reduced wind impact area.

This object is achieved with the solar system according to claim 1.

According to the first solution the solar modules are arranged at least two different angles of inclination relative to a flat, particularly horizontal, base area. This base area may be a flat roof.

Since the solar modules are provided with at least two different angles of inclination, the module-covered area can be enlarged considerably in comparison with the arrangement known from the prior art with only one fixed angle of inclination for all modules. Although the energy generation yield is lower for the modules of the second angle of inclination, which modules are not optimally arranged relative to the sun, an economic generation of energy is nevertheless possible with the solar system, especially in southern regions where the sun is very high and thus at a relatively flat angle of inclination.

In this context the angle of inclination is defined as the angle between the normal of the base area as the first leg and the normal of the solar module as the second leg.

Preferably, at least two solar modules can be arranged to adjoin each other at different angles of inclination. The spaces between them are thereby reduced, and the total area is thereby utilized in a further improved way.

Advantageously, solar modules with the same angle of inclination could be arranged in at least one row and, further preferably, rows with different angles of inclination could be arranged in alternating fashion. With such an arrangement, the area utilization is optimized, and installation is simultaneously simplified owing to the regular arrangement of the modules.

Furthermore, the solar modules can form a substantially closed area. Owing to the provision of a substantially closed area, wind impacts underneath the modules can be prevented or at least reduced. This moderates the demands made on the mounting of the system on the flat roof and on the flat, particularly horizontal, base area, respectively.

According to an advantageous embodiment the solar modules can be arranged such that the different angles of inclination are arranged in symmetry with the normal of the base area. This means that the surface normals of the solar modules of the one orientation and of the other orientation and the surface normals of the base area are substantially positioned in one plane, with the surface normals of the base area being positioned between the two other surface normals. This has inter alia the advantage that for modules with the second orientation the same support elements can be used.

According to another variant according to the invention the solar modules can be arranged such that the angle of inclination of the solar modules facing away from the sun is larger than that of the modules facing the sun. If the distance between two rows is smaller than the projection of the solar modules onto the base area, a closed surface can nevertheless be achieved with this design. It is particularly advantageous in this variant when the solar modules are substantially rectangular and solar modules adjoining each other are arranged at different angles of inclination such that a long side of one solar module abuts on a short side of an adjoining solar module.

According to a preferred embodiment at least two solar modules can be arranged at different angles of inclination on a support element. This simplifies installation on the one hand, and this design of the support element provides improved stability on the other hand.

The object of the invention is also achieved with the solar system in claim 10. In this design, a reflecting element is arranged between two solar modules. Said reflecting element serves to reflect as much light as possible towards the solar module, which light impinges into the intermediate area 15, 17. This improves the light yield of the solar modules as compared with the prior art.

Particularly preferably, the solar modules can be arranged substantially at an identical first angle of inclination relative to a flat, particularly horizontal, base area, and the reflecting element can be arranged at a second angle of inclination relative to the flat base area, with the surface normals of the solar modules, of the reflecting elements and of the base area being substantially positioned in one plane, and the surface normals of the base area being positioned between the surface normals of the solar modules and of the reflecting element. As a result, the solar modules can be oriented towards the sun, whereby as much light as possible, which light is impinging into the interspaces, can be reflected towards the solar modules. This further improves the total yield.

Advantageously, an edge of the reflecting element can abut on the edge of the one solar module that is arranged spaced apart from the base area, and the opposite edge of the reflecting element can abut on the edge of the other solar module that abuts on the base area. The total intermediate area is thereby efficiently covered with a reflecting element.

Particularly preferably, the solar modules and the intermediate reflecting element can thus form a substantially closed area. Due to the closed area, wind impact underneath the solar modules can be efficiently prevented.

Advantageously, the angle of inclination of the reflecting elements can be larger than the angle of inclination of the solar modules. When the distance of the rows of solar modules is smaller than the projection of a solar module onto the base area, a closed area with a high light yield can nevertheless by created thereby.

According to a preferred design at least one solar module and one reflecting element can be arranged on a support element. Hence, these form a module consisting of solar module and reflecting element, whereby installation, but also the stability of the system, can be improved.

Particularly preferably, the reflecting elements can be configured as mirror-reflecting or diffuse-reflecting elements. This can particularly be accomplished with metallic elements or metal-coated elements, but also by simply applying a white paint. These measures serve the enhanced light yield of the total solar system.

Preferred embodiments of the present invention shall now be explained with reference to the enclosed figures, in which:

FIG. 1 shows the arrangement of solar modules in a solar system according to the prior art;

FIG. 2 shows a first embodiment of a solar system according to the invention, in which modules opposite to the sun are also arranged;

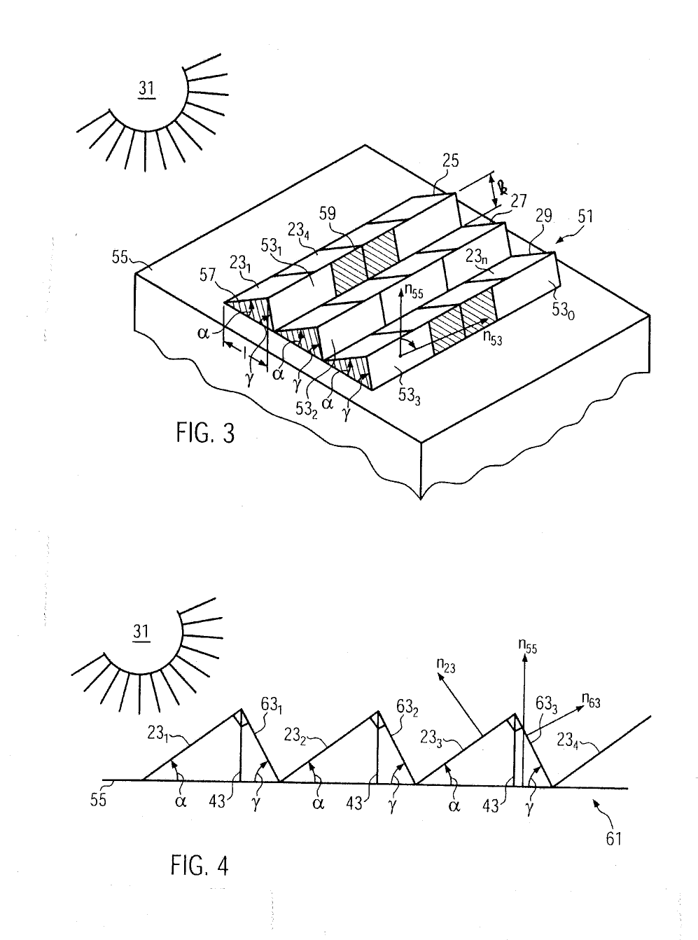

FIG. 3 shows a second embodiment with a variant of a solar system according to the invention; and

FIG. 4 shows a third embodiment with a reflecting element between two solar modules.

FIG. 2 shows the first embodiment of a solar system 21 according to the invention. In this embodiment, just like in the known solar system of FIG. 1, a plurality of solar modules 23ᵢ, with i=1, . . . , m are oriented towards the sun 31 in a plurality of rows 25, 27, 29 side by side at an angle of inclination α, which is substantially the same for all rows 25, 27, 29. The solar modules 23ᵢ, are preferably photovoltaic modules used for converting radiation, particularly sun light, into electric current. However, it would also be possible to design thermal solar systems in a corresponding way.

In contrast to the known solar systems (see FIG. 1), further solar modules 33ᵢ, with i=1, . . . , n are arranged in the system according to the invention also between the rows 25, 27, and 29. However, in comparison with the angle of inclination α of the first solar modules 23ᵢ the solar modules 33ᵢ, are oriented at a different angle of inclination β away from the sun. In this embodiment, the relation β=−α is substantially applicable to the two angles of inclination. This yields a symmetrical arrangement of the surface normals n₂₃ and n₃₃ of the solar modules 23ᵢ, and 33ᵢ respectively, relative to the surface normal n₃₇ of the flat roof 37, wherein the three normals n₂₃, n₃₃ and n₃₇ are positioned in one plane. In this embodiment the modules 23ᵢ, and 33ᵢ, are thus arranged in such a manner that a respective edge of a module 23ᵢ, abuts on a side edge of a module 33ᵢ except for the edge portions at the left side from row 25 and at the right side from row 29. This provides a closed zigzag-shaped area completely filled with solar modules.

Due to the use of solar modules with the same dimensions both for rows 25, 27 and 29 and for the oppositely arranged rows 39 and 41, it is possible to use the same support elements 43, 45 for both orientations. Two or more modules could possibly also be fastened particularly at different angles of inclination α, β to an integral holding element (not shown) to improve the stability of the structure. The open sides of the system could possibly be covered (shown in FIG. 2 by way of hatching).

Since the spaces between rows 25, 27 and 29 are filled with further solar modules 33ᵢ a considerably improved utilization of the area is achieved as compared with the prior art. Although the orientation of the modules of rows 39 and 41 is not optimum with respect to the sun 31, the generation of energy is nevertheless possible, which is particularly economic in southern regions. Due to the opposite arrangement of the solar modules 33ᵢ, relative to the modules 23ᵢ, there is also no further shading of the modules oriented towards the sun.

In comparison with the solar system of FIG. 1 there is the further advantage that the closed area efficiently prevents a lifting of the system caused by wind possibly passing underneath the modules. At least, however, the demands made on the mounting on the roof 37 are less strict in comparison with the mounting of the system in FIG. 1.

In the illustrated embodiment the modules 23ᵢ, and 33ᵢ, are directly adjoining one another to provide an optimum area yield. However, the modules may also be spaced apart from one another, e.g. for ventilation, but the distance for this purpose between two modules need only be a friction of the distance d shown in FIG. 1.

FIG. 3 shows a second embodiment of a solar system 51 according to the invention. In this system 51, solar modules 23₁ to 23ₙ are again optimally oriented, as already shown in the first embodiment, in rows 25, 27 and 29 at an angle of inclination αrelative to sun 31. In contrast to the first embodiment the modules 53ᵢ, with i=1, . . . , 0, which are oriented opposite to the sun, are again oriented at a different angle of inclination 7 opposite to the sun; in the second embodiment, however, said angle of inclination 7 is larger in its amount than the angle of inclination α: |γ|>α. As shown, the edges between two neighboring modules 23₁ and 53₁ abut on each other again.

This arrangement is of advantage whenever the distance between two rows 25, 27 is smaller than the length of the projection 1 of a module 23ᵢ onto the base area 55. It is here for instance possible to utilize the orientation of a normally rectangular solar module. While the modules 23ᵢ, oriented towards the sun are longitudinally oriented at an angle of inclination α, the modules 53ᵢ, facing away from the sun are oriented in a direction transverse to the angle of inclination γ. If in this configuration an intermediate space 59 is created between modules 53₁ and 53₄, with modules of the same size being used, (see row 25 and 29), said space can be covered with a panel that is particularly reflective.

Of particular advantage is the combination of two solar modules 23₁ and 23₄ oriented towards the sun with a module 53₁ oriented opposite to the sun, in one subassembly on a support element 57.

With the arrangement of FIG. 3 the same advantages are achieved as in the first embodiment. In addition, however, even more modules can be arranged on a given area due to the shorter distance.

FIG. 4 is a cross-sectional view showing a third embodiment of a solar system 61 according to the invention. Elements with reference numerals used already in FIG. 2 and FIG. 3 are not explained once again in detail; reference is herewith made to their description. In contrast to the second embodiment, solar modules are no longer used in the third embodiment at the side facing away from the sun, but instead of this reflecting areas 63ᵢ with i=1 to 3.

Said reflecting areas 63ᵢ may e.g. be mirror-reflecting metal surfaces or also diffuse-reflecting areas, for instance panels painted in white. Due to the mounting of reflecting areas 63ᵢ the energy yield of the whole system 61 is also improved in comparison with the system shown in FIG. 1 because light impinging into the interspaces 15, 17 (see FIG. 1) can nevertheless still impinge at least in part onto the neighboring solar modules 23₂, 23₃, whereby their yield is improved.

As shown in FIG. 4, a solar module 23ᵢ and a reflecting element 63ᵢ can be arranged on a joint holding element 43. In the embodiment as is here illustrated, the reflecting areas 63ᵢ have an angle of inclination γ like in the second embodiment, but an arrangement as shown in FIG. 2 with a symmetrical angle β is also possible.

To exploit the area in a further optimized way, the individual embodiments according to the invention may also be combined in any desired way.

What is claimed is:

1. A solar system comprising a plurality of solar modules, particularly photovoltaic modules, wherein the solar modules are arranged at least two different angles of inclination (α, β) relative to a flat, particularly horizontal, base area.

2. The solar system according to claim 1, wherein at least two solar modules are arranged, adjoining each other, at different angles of inclination (α, β).

3. The solar system according to claim 1, wherein solar modules are arranged at the same angle of inclination (α, β) in at least one row.

4. The solar system according to claim 3, wherein rows are alternatingly arranged at different angles of inclination (α, β).

5. The solar system according to claim 1, wherein the solar modules form an essentially closed area.

6. The solar system according to claim 1, wherein the solar modules are arranged such that the different angles of inclination (α, β) are in symmetry with the normal of the base area.

7. The solar system according to claim 1, wherein the solar modules are arranged such that the angle of inclination (γ) of the solar modules facing away from the sun is larger than the angle of inclination (α) of the modules facing the sun.

8. The solar system according to claim 7, wherein the solar modules are substantially rectangular and solar modules adjoining one another are arranged at different angles of inclination (α, γ) such that a long side of a solar module abuts on a short side of an adjoining solar module.

9. The solar system according to claim 1, wherein at least two solar modules are arranged at different angles of inclination on a support element.

10. A solar system comprising a plurality of solar modules, particularly photovoltaic modules, wherein a reflecting element is arranged between two solar modules.

11. The solar system according to claim 10, wherein the solar modules spaced apart from one another are substantially arranged at an identical first angle of inclination (α) relative to a flat, particularly horizontal, base area, and the reflecting element is arranged at a second angle of inclination (γ) relative to the flat base area, wherein the surface normals n₂₃ of the solar modules and n₆₃ of the reflecting element and n₅₅ of the base area are positioned substantially in one plane, and the surface normal of the base area is positioned between the surface normals n₂₃ of the solar modules and n₆₃ of the reflecting element.

12. The solar system according to claim 10, wherein an edge of the reflecting element abuts on the edge of the one solar module that is spaced apart from the base area, and the opposite edge of the reflecting element abuts on the edge of the other solar module that abuts on the base area.

13. The solar system according to claim 11, wherein the solar modules and the interposed reflecting element form a substantially closed area.

14. The solar system according to claim 10, wherein the angle of inclination (γ) of the reflecting elements is larger than the angle of inclination (α) of the solar modules.

15. The solar system according to claim 10, wherein at least one solar module and one reflecting element are arranged on a support element.

16. The solar system according to claim 10, wherein the reflecting elements are minor-reflecting or diffuse-reflecting elements.
